(19) United States
(12) Patent Application Publication
(10) Pub. No.: US 2012/0216857 A1
(43) Pub. Date: Aug. 30, 2012

(54) Solar Cell Assembly with an Improved Photocurrent Collection Efficiency

(75) Inventors: Yu-Li Tsai, Changhua County (TW); Chih-Hung Wu, Taoyuan County (TW)

(73) Assignee: ATOMIC ENERGY COUNCIL-INSTITUTE OF NUCLEAR ENERGY RESEARCH, Taoyuan County (TW)

(21) Appl. No.: 13/036,054

(22) Filed: Feb. 28, 2011

(51) Int. Cl. H01L 31/0216; H01L 31/06

(52) U.S. Cl. 136/255; 136/256

(57) ABSTRACT

Disclosed is a solar cell assembly with excellent photocurrent collection efficiency. The solar cell assembly includes a solar cell and a surface barrier layer. The solar cell includes a window layer. The surface barrier layer is provided on the window layer. The surface barrier layer is made of phosphide or arsenide.

### BACKGROUND OF INVENTION

1. Field of Invention

The present invention relates to a solar cell assembly and, more particularly, to a solar cell assembly with an improved photocurrent collection efficiency.

2. Related Prior Art

Referring to FIG. 7, a conventional solar cell 3 includes a substrate 31, a back surface field layer 32, a base layer 33, an emitter layer 34, a window layer 35 and a contact layer 36. The window layer 35 reduces surface recombination loss of photocurrent near the surface of the emitter layer 34 and hence increases the carrier-collection efficiency.

From paths a, b and c for transmitting and collecting the photocurrent generated by the solar cell 3 irradiated by sun light, it can be found that the window layer 35 reduces the recombination of the photocurrent near the surface of the emitter layer 34 but it does not avoid the recombination loss of the photocurrent near the surface thereof, particularly in a light-concentrating condition. Take the paths a, b and c for example. Along the path a, the surface recombination is the lowest, and the collection efficiency is the highest. Along the path c, the surface recombination is the highest, and the collection efficiency is the lowest. Along the path b, both of the surface recombination and the collection efficiency are medium. However, most of the photocurrent is generated along the path c. Therefore, it is an important issue to reduce the surface recombination along the path c to increase the carrier-collection efficiency in a light-concentrating solar cell.

There have been various documents advocating sulfur passivation to reduce the surface recombination near the upper surface of the window layer to increase the carrier-collection efficiency. For the sulfur passivation, there are various solutions including Na₂S, (NH₄)₂S and (NH₄)₂Sₓ. The use of (NH₄)₂Sₓ for the sulfur passivation provides a satisfactory result. For example, if the window layer is made of AlInP, without the sulfur passivation, there would be many oxygen-related bonds near the upper surface of the window layer including In—O bonds and Al—O bonds. These bonds are recombination centers. These surface states could easily capture the photocurrent to increase the surface recombination rate. With the sulfur passivation, the oxygen-related bonds are replaced with sulfur-related bonds. That is, the In—O bonds and Al—O bonds are replaced with In—S bonds and Al—S bonds to reduce the surface state density and the surface recombination. However, there are concerns about the sulfur passivation of the upper surface of the window layer as follows:
1. There might be side reactions of the (NH₄)₂Sₓ solution with the other layers of the solar cell; and
2. The stability of the solar cell against the temperature might be affected. The stability against the temperature is particularly important for a light-concentrating solar cell.

There are of course other approaches other than the sulfur passivation. Some documents propose reducing the surface recombination by selecting proper materials for the window layer. The materials can be classified to a lattice-matched type and a lattice-mismatched type. An oxide layer can be used to reduce dangling bonds. These techniques can be found in various documents as follows:
1. U.S. Pat. No. 4,276,137, “Control of surface recombination loss in solar cells”;
2. U.S. Pat. No. 7,119,271, “Lattice-mismatched window layer for a solar conversion Device”;
3. U.S. Pat. No. 7,763,917, “Photovoltaic devices with silicon dioxide encapsulation layer and method to make same”;
4. U.S. Pat. No. 4,935,384, “Method of passivating semiconductor surfaces”;
5. Taiwanese Patent Application Publication No. 200901493;
6. Taiwanese Patent Application Publication No. 200814344; and
7. Taiwanese Patent Application Publication No. 200841478.

Regarding the above-mentioned documents, no matter the window layer is made of a lattice-matched or lattice-mismatched material, or an oxide layer is provided on the window layer, there are still oxygen-related defects on the upper surface of the window layer that reduce the photocurrent collection efficiency.

The present invention is therefore intended to obviate or at least alleviate the problems encountered in the prior art.

### SUMMARY OF INVENTION

It is the primary objective of the present invention to provide a solar cell assembly with an improved photocurrent collection efficiency.

To achieve the foregoing objectives, the solar cell assembly includes a solar cell and a surface barrier layer provided on the solar cell. The surface barrier layer is made of phosphide or arsenide.

In an aspect, the solar cell includes at least one substrate, a buffer layer provided on the substrate, a back surface field layer provided on the buffer layer, a base layer provided on the back surface field layer, an emitter layer provided on the base layer, a window layer provided on the emitter layer, and a contact layer provided on the window layer.

In another aspect, the solar cell includes a substrate, a buffer layer provided on the substrate, a first back surface field layer provided on the buffer layer, a first base layer provided on the first back surface field layer, a first emitter layer provided on the first base layer, a first window layer provided on the first emitter layer, a second back surface field layer provided on the first window layer, a second base layer provided on the second back surface field layer, a second emitter layer provided on the second base layer, a second window layer provided on the second emitter layer, and a contact layer provided on the second window layer.

In another aspect, the solar cell includes a substrate, a seed layer provided on the substrate, a first back surface field layer provided on the seed layer, a first base layer provided on the first back surface field layer, a first emitter layer provided on the first base layer, a first window layer provided on the first emitter layer, a second back surface field layer provided on the first window layer, a second base layer provided on the second back surface field layer, a second emitter layer provided on the second base layer, a second window layer provided on the second emitter layer, and a contact layer provided on the second window layer.

In another aspect, the window layer is made of p-type AlGaAs while the surface barrier layer is made of n-type AlGaInP.

In another aspect, the window layer is made of p-type AlGaAs while the surface barrier layer is made of p-type AlGaInP.

In another aspect, the window layer is made of p-type AlGaInP while the surface barrier layer is made of n-type Al_{y}Ga_{1-y}As, wherein y=0 to 1.

In another aspect, the window layer is made of p-type AlGaInP while the surface barrier layer is made of p-type Al_{z}Ga_{1-z}As, wherein z=0 to 1.

In another aspect, the surface barrier layer is made in a lithography process including the steps of coating photo-resist, soft baking, exposure, hard baking, development, partial etching of the surface barrier layer, and removing the photo-resist.

Other objectives, advantages and features of the present invention will be apparent from the following description referring to the attached drawings.

### BRIEF DESCRIPTION OF DRAWINGS

The present invention will be described via detailed illustration of three embodiments versus prior the art referring to the drawings wherein:

FIG. 1 is a cross-sectional view of a solar cell assembly according to the first embodiment of the present invention;

FIG. 2 is a cross-sectional view of a semi-product of the solar cell assembly shown in FIG. 1;

FIG. 3 is a cross-sectional view of another semi-product of the solar cell assembly according to FIG. 1;

FIG. 4 is another cross-sectional view of the solar cell assembly shown in FIG. 1, with various paths for photocurrent shown in phantom lines;

FIG. 5 is a cross-sectional view of a solar cell assembly according to the second embodiment of the present invention;

FIG. 6 is a cross-sectional view of a solar cell assembly according to the third embodiment of the present invention; and

FIG. 7 is a cross-sectional view of a conventional solar cell assembly.

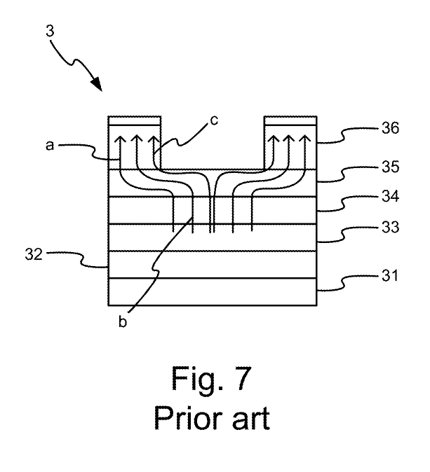

### DETAILED DESCRIPTION OF EMBODIMENTS

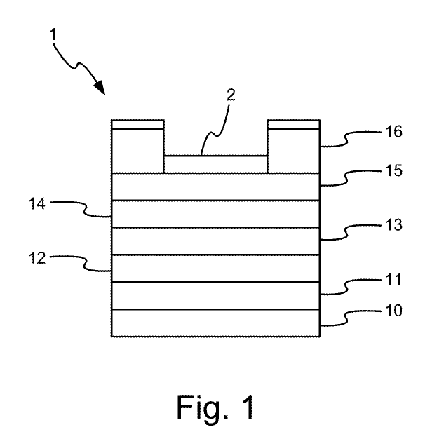

Referring to FIG. 1, there is shown a solar cell assembly with excellent photocurrent collection efficiency according to the first embodiment of the present invention. The solar cell assembly includes a solar cell 1 and a surface barrier layer 2.

The solar cell 1 includes at least one substrate 10, a buffer layer 11 provided on the substrate 10, a back surface field layer 12 provided on the buffer layer 11, a base layer 13 provided on the back surface field layer 12, an emitter layer 14 provided on the base layer 13, a window layer 15 provided on the emitter layer 14, and a contact layer 16 provided on the window layer 15. The solar cell 1 is a single-junction solar cell.

The surface barrier layer 2 is provided on the window layer 15. The surface barrier layer 2 is made of phosphide or arsenide.

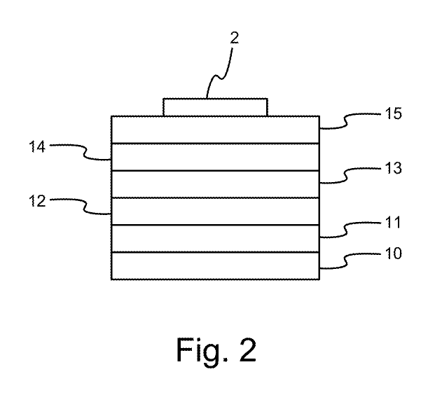

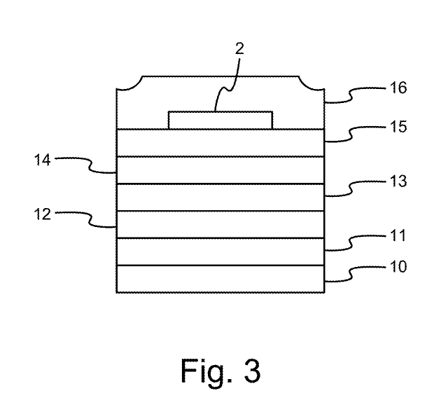

The production of the solar cell assembly will be described referring to FIGS. 2 and 3. At first, the surface barrier layer 2 is provided on the window layer 15 in a lithography process including the steps of coating photo-resist, soft baking, exposure, hard baking, development, partial etching of the surface barrier layer 2, and removing the photo-resist. Then, re-growth is done on the window layer 15 by metal organic chemical vapor deposition (“MOCVD”). Thus, the heavily doped p-type GaAs contact layer 16 is made. Finally, a typical chip process for making a solar cell is executed to provide the solar cell assembly with the surface barrier layer 2 provided on the solar cell 1.

In the first embodiment, the substrate 10 is made of n-type GaAs, and the window layer 15 is made of p-type AlGaAs. Therefore, after the forming of the window layer 15, the n-type AIInP surface barrier layer 2 is formed to reduce the surface recombination near the window layer 15 and hence increase the carrier-collection efficiency and the conversion efficiency of the solar cell assembly.

Furthermore, the material of the surface barrier layer 2 is determined according to the material of the window layer 15. For example, if the window layer 15 is made of p-type AlGaAs, the surface barrier layer 2 can be made of n-type (AlₓGa₁₋ₓ)_{0.5}In_{0.5}P (x=0 to 1) or p-type (Al_{y}Ga_{1-y})_{0.5}In_{0.5}P (y=0 to 1). If the window layer 15 is made of p-type (AlₓGa₁₋ₓ)^{0.5}In_{0.5}P, the surface barrier layer 2 can be made of n-type Al_{y}Ga_{1-y}As (y=0 to 1) or p-type Al_{z}Ga_{1-z}As (z=0 to 1). Of course, regarding lattice-mismatched solar cells, the window layer may be made of another material than AlGaAs and (AlₓGa₁₋ₓ)^{0.5}In_{0.5}P, and the material of the surface barrier layer changes.

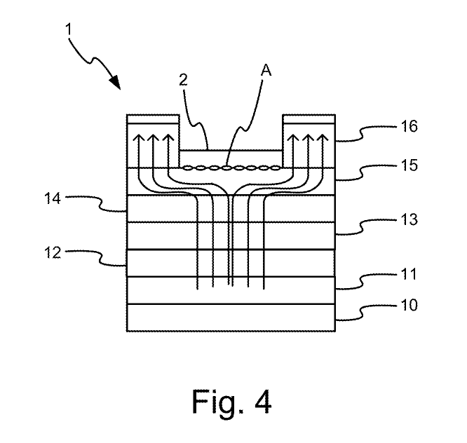

Referring to FIG. 4, in use, no matter the surface barrier layer 2 is made of n-type AlGaInP or p-type AlGaInP, there is a built-in electric field A between the surface barrier layer 2 and the window layer 15. The built-in electric field A effectively pushes photocurrent away from the surface of the window layer 15 and considerably reduces the recombination of the photocurrent near the surface of the window layer 15 and increases the conversion efficiency of the solar cell assembly.

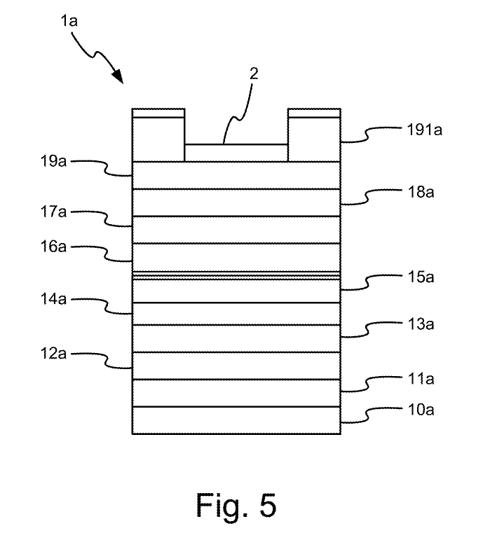

Referring to FIG. 5, there is shown a solar cell assembly according to a second embodiment of the present invention. The second embodiment is like the first embodiment except including a solar cell 1a instead of the solar cell 1. The solar cell 1a includes a substrate 10a, a buffer layer 11a provided on the substrate 10a, a first back surface field layer 12a provided on the buffer layer 11a, a first base layer 13a provided on the first back surface field layer 12a, a first emitter layer 14a provided on the first base layer 13a, a first window layer 15a provided on the first emitter layer 14a, a second back surface field layer 16a provided on the first window layer 15a, a second base layer 17a provided on the second back surface field layer 16a, a second emitter layer 18a provided on the second base layer 17a, a second window layer 19a provided on the second emitter layer 18a, and a contact layer 191a provided on the second window layer 19a. The solar cell 1a is a double-junction solar cell. The surface barrier layer 2 is provided on the second window layer 19a in the second embodiment like it is provided on the window layer 15 in the first embodiment.

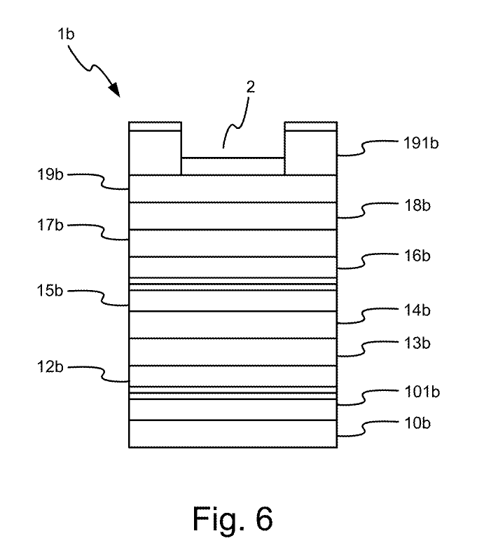

Referring to FIG. 6, there is shown a solar cell assembly according to a third embodiment of the present invention. The third embodiment is like the first embodiment except including a solar cell 1b instead of the solar cell 1. The solar cell 1b includes a substrate 10b, a seed layer 101b provided on the substrate 10b, a first back surface field layer 12b provided on the seed layer 101b, a first base layer 13b provided on the first back surface field layer 12b, a first emitter layer 14b provided on the first base layer 13b, a first window layer 15b provided on the first emitter layer 14b, a second back surface field layer 16b provided on the first window layer 15b, a second base layer 17b provided on the second back surface field layer 16b, a second emitter layer 18b provided on the second base layer 17b, a second window layer 19b provided on the second emitter layer 18b, and a contact layer 191b provided on the second window layer 19b. The solar cell 1b is a triple-junction solar cell. The surface barrier layer 2 is provided on the second window layer 19b in the third embodiment like it is provided on the window layer 15 in the first embodiment.

As discussed above, the solar cell assembly of the present invention increases the photocurrent collection efficiency and overcomes the problems encountered in the prior art. The built-in electric field is defined between the surface barrier layer and the window layer to protect the photocurrent generated by the solar cell assembly irradiated by the sun light. The built-in field pushes the photocurrent away from the recombination centers on the surface of the window layer and reduces surface recombination to increase the collection efficiency of the photocurrent.

The present invention has been described via the detailed illustration of the preferred embodiment. Those skilled in the art can derive variations from the preferred embodiment without departing from the scope of the present invention. Therefore, the preferred embodiment shall not limit the scope of the present invention defined in the claims.

1. A solar cell assembly including a solar cell 1 and a surface barrier layer 2 provided on the solar cell 1, wherein the surface barrier layer 2 is made of a material selected from the group consisting of phosphide and arsenide.

2. The solar cell assembly according to claim 1, wherein the solar cell 1 includes at least one substrate 10, a buffer layer 11 provided on the substrate 10, a back surface field layer 12 provided on the buffer layer 11, a base layer 13 provided on the back surface field layer 12, an emitter layer 14 provided on the base layer 13, a window layer 15 provided on the emitter layer 14, and a contact layer 16 provided on the window layer 15.

3. The solar cell assembly according to claim 1, wherein the solar cell 1a includes a substrate 10a, a buffer layer 11a provided on the substrate 10a, a first back surface field layer 12a provided on the buffer layer 11a, a first base layer 13a provided on the first back surface field layer 12a, a first emitter layer 14a provided on the first base layer 13a, a first window layer 15a provided on the first emitter layer 14a, a second back surface field layer 16a provided on the first window layer 15a, a second base layer 17a provided on the second back surface field layer 16a, a second emitter layer 18a provided on the second base layer 17a, a second window layer 19a provided on the second emitter layer 18a, and a contact layer 191a provided on the second window layer 19a.

4. The solar cell assembly according to claim 1, wherein the solar cell 1b includes a substrate 10b, a seed layer 101b provided on the substrate 10b, a first back surface field layer 12b provided on the seed layer 101b, a first base layer 13b provided on the first back surface field layer 12b, a first emitter layer 14b provided on the first base layer 13b, a first window layer 15b provided on the first emitter layer 14b, a second back surface field layer 16b provided on the first window layer 15b, a second base layer 17b provided on the second back surface field layer 16b, a second emitter layer 18b provided on the second base layer 17b, a second window layer 19b provided on the second emitter layer 18b, and a contact layer 191b provided on the second window layer 19b.

5. The solar cell assembly according to claim 1, wherein the window layer 15 is made of p-type AlGaAs, wherein the surface barrier layer 2 is made of n-type AlGaInP.

6. The solar cell assembly according to claim 1, wherein the window layer 15 is made of p-type AlGaAs, wherein the surface barrier layer 2 is made of p-type AlGaInP.

7. The solar cell assembly according to claim 1, wherein the window layer 15 is made of p-type AlGaInP, wherein the surface barrier layer 2 is made of n-type Al_{y}Ga_{1-y}As, wherein y=0 to 1.

8. The solar cell assembly according to claim 1, wherein the window layer 15 is made of p-type AlGaInP, wherein the surface barrier layer 2 is made of p-type Al_{z}Ga_{1-z}As, wherein z=0 to 1.

9. The solar cell assembly according to claim 1, wherein the surface barrier layer 2 is made in a lithography process including the steps of coating photo-resist, soft baking, exposure, hard baking, development, partial etching of the surface barrier layer 2, and removing the photo-resist.
